(19) United States
(12) Patent Application Publication
(10) Pub. No.: US 2025/0110397 A1
(43) Pub. Date: Apr. 3, 2025

(54) GENERATION METHOD, LEARNING METHOD, STORAGE MEDIUM, GENERATION APPARATUS, EVALUATION APPARATUS, FILM FORMING SYSTEM, AND ARTICLE MANUFACTURING METHOD

(71) Applicant: CANON KABUSHIKI KAISHA, Tokyo (JP)

(72) Inventors: SATORU JIMBO, Tokyo (JP); HIROSHI EBISUYU, Kanagawa (JP)

(21) Appl. No.: 18/889,591

(22) Filed: Sep. 19, 2024

(30) Foreign Application Priority Data
Sep. 28, 2023 (JP) 2023-168867

(51) Int. Cl. G03F 7/00

(52) U.S. Cl. CPC G03F 7/0002

(57) ABSTRACT

The present invention provides a generation method of generating, by an information processing apparatus, training data of a model used to evaluate a film of a composition formed on a substrate using a mold, comprising: generating a training image as the training data by processing a design image indicating a geometric feature of at least a part of the substrate.

### BACKGROUND OF THE INVENTION

### Field of the Invention

The present invention relates to a generation method, a learning method, a storage medium, a generation apparatus, an evaluation apparatus, a film forming system, and an article manufacturing method.

### Description of the Related Art

Imprint techniques that are techniques of forming a film having a fine pattern on a substrate are being put into practical use. One of the imprint techniques is a photo-curing method. In an imprint apparatus employing the photo-curing method, in a state in which a mold (original) is in contact with an imprint material (curable composition) supplied onto a substrate, the imprint material is irradiated with light and thus cured. After that, the mold is separated from the cured imprint material, thereby forming a film (cured film) of the imprint material having a pattern on the substrate. For example, to manufacture a semiconductor device or the like, an apparatus to which step and flash imprint lithography is applied is effective (Japanese Patent Laid-Open No. 2019-80047).

When forming a film of an imprint material on a substrate using the imprint technique that is one of film forming techniques, if the supply amount of an imprint material is too large, the imprint material may protrude (extrude) outward from the pattern region of the mold (to be sometimes referred to as protrusion hereinafter). On the other hand, in some cases, if the supply amount of the imprint material is too small, the imprint material is not spread on the entire pattern region of the mold, and the film of the imprint material is not partially formed (to be sometimes referred to as unfilling hereinafter). If protrusion occurs, the portion of the protrusion causes an imprint material film formation failure, and additionally, the pattern of the mold that comes into contact with that portion is broken. Also, if unfilling occurs, the film of the imprint material is not formed on that portion, and therefore, a defective semiconductor device is formed.

For this reason, it is necessary to detect the presence/absence of protrusion or unfilling after the imprint process and adjust the supply amount and position of the imprint material in accordance with the result of the detection to prevent an imprint material film formation failure. However, since protrusion or unfilling occurs in a very small region, an enormous number of observation images obtained by a high magnification microscope with a small detection range need to be confirmed, and it is difficult to manually perform this. Hence, there is a demand for a technique of inspecting protrusion or unfilling from an observation image and detecting an imprint material film formation failure caused by protrusion or unfilling (that is, evaluating the film of the imprint material) without intervention of manpower. The imprint material film formation failure caused by protrusion or unfilling will sometimes be referred to as an “abnormality” hereinafter.

As a method of detecting an abnormality from an observation image, a method using machine learning can be used. In this method, a model that receives an observation image as an input and outputs an abnormality detection result is generated by machine learning, and an abnormality can be detected using the model. To accurately generate such a model by machine learning, an enormous number of images to which the features of abnormalities are added need to be prepared in advance as training data. However, it is cumbersome to perform an imprint process to prepare an enormous number of images serving as training data while changing conditions to change the position and size of an abnormality included in an image, and it takes a pretty long time.

### SUMMARY OF THE INVENTION

The present invention provides, for example, a technique advantageous for easily generating training data of a model configured to evaluate a film of a composition formed on a substrate using a mold.

According to one aspect of the present invention, there is provided a generation method of generating, by an information processing apparatus, training data of a model used to evaluate a film of a composition formed on a substrate using a mold, comprising: generating a training image as the training data by processing a design image indicating a geometric feature of at least a part of the substrate.

Further features of the present invention will become apparent from the following description of exemplary embodiments with reference to the attached drawings.

### BRIEF DESCRIPTION OF THE DRAWINGS

FIGS. 1A and 1B are views showing an example of the configuration of an imprint apparatus;

FIG. 2 is a view showing an example of the configuration of a wide-angle alignment measurement device;

FIG. 3 is a view showing an example of the configuration of an article manufacturing system;

FIG. 4 is a view showing an example of the configuration of an evaluation apparatus;

FIG. 5 is a flowchart showing the operation of the imprint apparatus;

FIGS. 6A and 6B are views showing protrusion and unfilling;

FIGS. 7A to 7C are views showing images including protrusion and unfilling;

FIGS. 8A and 8B are views showing unfilling that occurs in marks;

FIG. 9 is a schematic view showing a method of generating an evaluation model by machine learning and a method of evaluating a film on a substrate using the evaluation model;

FIG. 10 is a flowchart showing the method of generating an evaluation model by machine learning;

FIG. 11 is a flowchart showing the method of evaluating a film on a substrate using the evaluation model;

FIG. 12 is a flowchart showing a training image generation method;

FIGS. 13A and 13B are views showing an example of a design image;

FIG. 14 is a schematic view for explaining processing performed by a generation apparatus;

FIGS. 15A and 15B are schematic views for explaining processing performed by a creation unit;

FIG. 16 is a schematic view for explaining processing performed by a generation unit; and

FIG. 17 is a view for explaining an article manufacturing method.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made an invention that requires all such features, and multiple such features may be combined as appropriate. Furthermore, in the attached drawings, the same reference numerals are given to the same or similar configurations, and redundant description thereof is omitted.

The following embodiment is related to a film forming system including a film forming apparatus. The film forming apparatus is used to manufacture a device such as a semiconductor device as an article, arranges a composition in an uncured state (liquid state) on a substrate, shapes the arranged composition by a mold, and forms a film of the composition on the substrate. The film forming apparatus may be called a shaping apparatus, and a film forming process may be called a shaping process.

The film forming process includes a contact step of bringing a curable composition (shapable material) supplied onto a substrate and a mold (an original or a template) into contact with each other. By the contact step, a film of the curable composition shaped by the mold is formed on the substrate. The film forming process can further include a curing step of curing the curable composition in a state in which the curable composition and the mold are in contact. By the curing step, the film of the curable composition formed on the substrate is cured, and a cured film made of a cured product of the curable composition is formed on the substrate. The film forming process can further include a separation step of separating the cured film made of the cured product of the curable composition from the mold.

The film forming apparatus can be used as an imprint apparatus that performs an imprint process of transferring the pattern of the mold to an imprint material by bringing the imprint material that is the curable composition supplied onto a shot region of the substrate into contact with the pattern region of the mold. The pattern of the mold can be, for example, the pattern of a semiconductor device (device pattern). The shot region is a region where a pattern made of the cured product of the imprint material should be formed, and a plurality of shot regions are arrayed on the substrate. The imprint apparatus can individually perform the imprint process (film forming process) for each of the plurality of shot regions on the substrate. The imprint apparatus may be configured to perform the imprint process collectively for at least two shot regions among the plurality of shot regions on the substrate (for the entire surface of the substrate or for the shot regions in one or two or more columns). Also, the film forming apparatus can be used as a planarization apparatus that performs a planarization process of bringing a curable composition on a substrate into contact with a member with a flat surface (a flat surface of a mold), thereby forming a planarized film of the curable composition on the substrate. Hereinafter, in order to show a specific example, a system including the imprint apparatus that is an example of the film forming apparatus will be described.

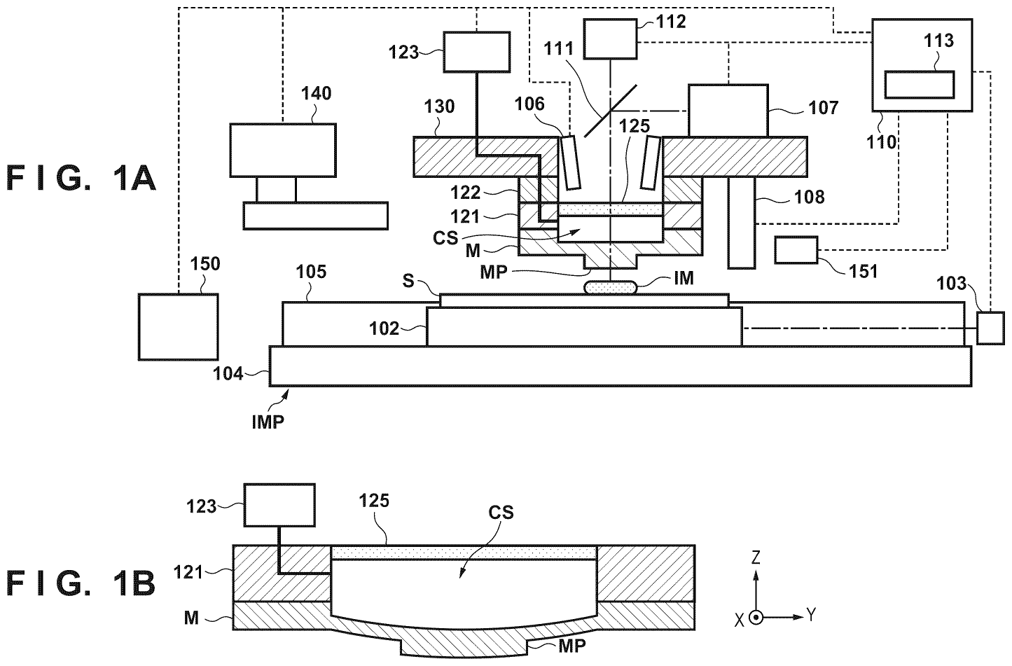

FIG. 1A schematically shows an example of the configuration of an imprint apparatus IMP according to an embodiment of the present invention. The imprint apparatus IMP performs an imprint process of curing an imprint material IM in a state in which the imprint material IM on a substrate S is in contact with a pattern region MP of a mold M and separating a cured product of the imprint material IM from mold M. By the imprint process, a pattern made of the cured product of the imprint material IM is formed on the substrate S.

As the imprint material IM, a curable composition (to be also referred to as a resin in an uncured state) that is cured by receiving curing energy is used. Examples of the curing energy can be an electromagnetic wave, heat, and the like. The electromagnetic wave can be, for example, light selected from the wavelength range of 10 nm (inclusive) to 1 mm (inclusive), for example, infrared light, a visible light beam, ultraviolet light, or the like. The curable composition can be a composition cured with light irradiation or heating. A photo-curable composition cured by light irradiation contains at least a polymerizable compound and a photopolymerization initiator, and may further contain a nonpolymerizable compound or a solvent as needed. The nonpolymerizable compound is at least one material selected from the group consisting of a sensitizer, a hydrogen donor, an internal mold release agent, a surfactant, an antioxidant, and a polymer component. The imprint material can be arranged on the substrate S in the form of droplets or in the form of an island or film obtained by connecting a plurality of droplets. The viscosity (the viscosity at 25° C.) of the imprint material IM can be, for example, 1 mPa⋅s (inclusive) to 100 mPa⋅s (inclusive). As the material of the substrate, for example, glass, a ceramic, a metal, a semiconductor, a resin, or the like can be used. A member made of a material different from the substrate S may be provided on the surface of the substrate S, as needed. The substrate S is, for example, a silicon wafer, a compound semiconductor wafer, or silica glass.

In the specification and the accompanying drawings, directions will be indicated on an XYZ coordinate system in which directions parallel to the surface of the substrate S are defined as the X-Y plane. Directions parallel to the X-axis, the Y-axis, and the Z-axis of the XYZ coordinate system are the X direction, the Y direction, and the Z direction, respectively. A rotation about the X-axis, a rotation about the Y-axis, and a rotation about the Z-axis are θX, θY, and θZ, respectively. Control or driving concerning the X-axis, the Y-axis, and the Z-axis means control or driving concerning a direction parallel to the X-axis, a direction parallel to the Y-axis, and a direction parallel to the Z-axis, respectively. In addition, control or driving concerning the θX-axis, the θY-axis, and the θZ-axis means control or driving concerning a rotation about an axis parallel to the X-axis, a rotation about an axis parallel to the Y-axis, and a rotation about an axis parallel to the Z-axis, respectively. In addition, a position is information that can be specified based on coordinates on the X-, Y-, and Z-axes, and a posture is information that can be specified by values on the θX-, θY-, and θZ-axes. Positioning means controlling the position and/or posture. Alignment includes controlling the position and/or posture of at least one of the substrate and the mold.

The imprint apparatus IMP can include a substrate holder 102 that holds the substrate S, a substrate driving mechanism 105 that drives the substrate S by driving the substrate holder 102, a base 104 that supports the substrate holder 102, and a position measurement unit 103 that measures the position of the substrate holder 102. The substrate driving mechanism 105 can include, for example, a motor such as a linear motor.

The imprint apparatus IMP can include a mold holder 121 that holds the mold M, a mold driving mechanism 122 that drives the mold M by driving the mold holder 121, and a support structure 130 that supports the mold driving mechanism 122. The mold driving mechanism 122 can include, for example, a motor such as a voice coil motor.

The substrate driving mechanism 105 and the mold driving mechanism 122 form a driving mechanism that adjusts a relative position and a relative posture between the substrate S and the mold M. The adjustment of the relative position between the substrate S and the mold M by the driving mechanism includes driving for bringing the mold M into contact with the imprint material IM on the substrate S and separating the mold M from the cured imprint material IM (a pattern made of the cured product). The substrate driving mechanism 105 can be configured to drive the substrate S concerning a plurality of axes (for example, three axes including the X-axis, Y-axis, and θZ-axis, and preferably six axes including the X-axis, Y-axis, Z-axis, θX-axis, θY-axis, and θZ-axis). The mold driving mechanism 122 can be configured to drive the mold M concerning a plurality of axes (for example, three axes including the Z-axis, θX-axis, and θY-axis, and preferably six axes including the X-axis, Y-axis, Z-axis, θX-axis, θY-axis, and θZ-axis).

The imprint apparatus IMP can include a mold conveyance mechanism 140 that conveys the mold M, and a mold cleaner 150. The mold conveyance mechanism 140 can be configured to, for example, convey the mold M to the mold holder 121 and convey the mold M from the mold holder 121 to an original stocker (not shown), the mold cleaner 150, or the like. The mold cleaner 150 cleans the mold M by using ultraviolet light, a chemical solution, or the like.

The imprint apparatus IMP can include a deformation mechanism 123 that deforms the pattern region MP of the mold M into a convex shape toward the substrate S, as schematically shown in FIG. 1B. The mold holder 121 is provided with a window member 125 configured to form a pressure-controlled space CS on the side of the reverse surface of the mold M (the surface on the side opposite to the pattern region MP on which the pattern to be transferred to the substrate S is formed). The deformation mechanism 123 can deform the pattern region MP of the mold M by controlling the pressure (to be referred to as a cavity pressure hereinafter) of the pressure-controlled space CS.

The imprint apparatus IMP can include an alignment measurement device 106, a wide-angle alignment measurement device 151, a curing unit 107, an image capturing unit 112, and an optical member 111. The alignment measurement device 106 illuminates an alignment mark of the substrate S and an alignment mark of the mold M and captures the images of the marks, thereby measuring the relative position between the marks. The alignment measurement device 106 can be positioned by a driving mechanism (not shown) in accordance with the positions of the alignment marks to be observed. The wide-angle alignment measurement device 151 is a measurement device having a field wider than that of the alignment measurement device 106. The wide-angle alignment measurement device 151 illuminates an alignment mark of the substrate S and captures the image of the alignment mark, thereby measuring the position of the substrate S. By measuring the position of the substrate S by the wide-angle alignment measurement device, it is possible to move the alignment mark of the substrate S into the field of the alignment measurement device 106.

The curing unit 107 irradiates the imprint material IM with an energy (for example, light such as ultraviolet light) for curing the imprint material IM via the optical member 111, thereby curing the imprint material IM. The image capturing unit 112 captures images of the substrate S, the mold M, and the imprint material IM via the optical member 111 and the window member 125.

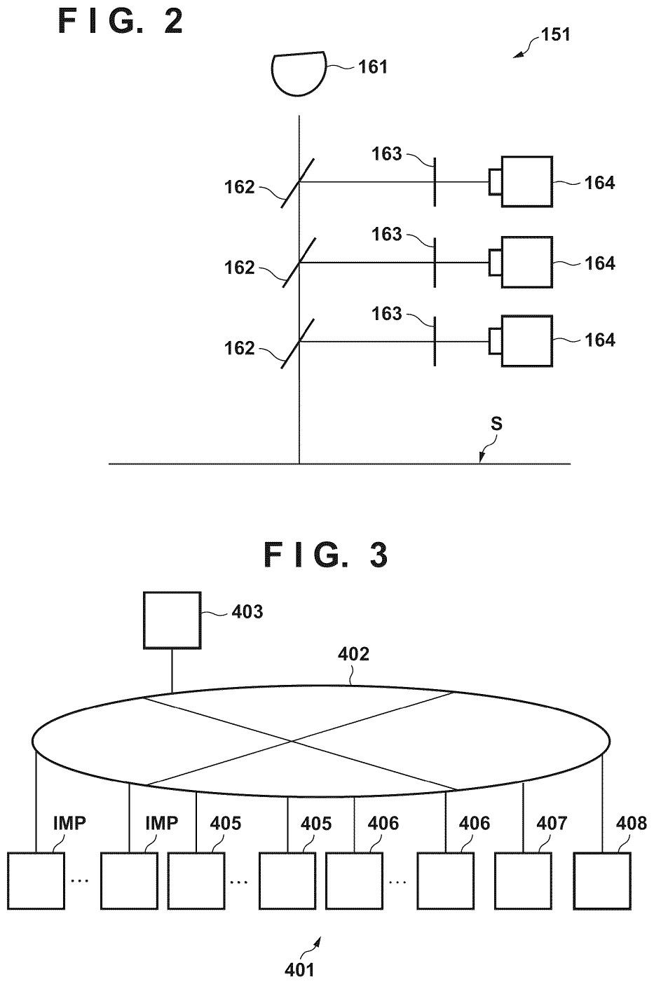

The wide-angle alignment measurement device 151 may include a mechanism for switching the wavelength of illumination light. For example, the wide-angle alignment measurement device 151 includes a wavelength filter arranged on an optical path, and a mechanism for switching the wavelength filter. Alternatively, as shown in FIG. 2, the wide-angle alignment measurement device 151 may have a configuration capable of simultaneously capturing of images of a plurality of wavelengths. The wide-angle alignment measurement device 151 shown in FIG. 2 includes a light source 161, a plurality of half mirrors 162 each of which branches the optical path, a plurality of wavelength filters 163 that transmit different wavelengths, and a plurality of imaging elements 164, and can simultaneously capture images of different wavelengths. Also, the wide-angle alignment measurement device 151 may include a mechanism for switching the light amount of illumination light. For example, the wide-angle alignment measurement device 151 may include a mechanism for switching an ND filter arranged on the optical path. Furthermore, the wide-angle alignment measurement device 151 may include a plurality of optical systems such as a bright-field optical system and a dark-field optical system, and a mechanism for switching the optical system through which the image to be captured passes. The wide-angle alignment measurement device 151 may include a mechanism for switching polarization of illumination light or received light. For example, the wide-angle alignment measurement device 151 may include a mechanism for switching a polarizing filter arranged on the optical path.

The imprint apparatus IMP can include a dispenser 108 that arranges (supplies) the imprint material IM on the substrate S. For example, the dispenser 108 discharges the imprint material IM such that the imprint material IM is arranged on the substrate S in accordance with a drop recipe indicating the arrangement of the imprint material IM.

The imprint apparatus IMP can include a controller 110 that controls the substrate driving mechanism 105, the mold driving mechanism 122, the deformation mechanism 123, the mold conveyance mechanism 140, the mold cleaner 150, the alignment measurement device 106, the curing unit 107, the image capturing unit 112, the dispenser 108, and the like. The controller 110 can include an information processing apparatus 113 (computer) including a processor such as a central processing unit (CPU), and a storage unit such as a memory. The controller 110 may be formed by, for example, a PLD (a short for Programmable Logic Device) such as an FPGA (a short for Field Programmable Gate Array), an ASIC (a short for Application Specific Integrated Circuit), a general-purpose computer installed with a program, or a combination of all or some of these components.

FIG. 3 exemplarily shows the configuration of an article manufacturing system 401 for manufacturing an article such as a semiconductor device. The article manufacturing system 401 can include, for example, one or a plurality of imprint apparatuses IMP (film forming apparatuses) and one or a plurality of inspection apparatuses 405 (for example, an overlay inspection apparatus, a CD inspection apparatus, a defect inspection apparatus, and an electrical characteristics inspection apparatus). The article manufacturing system 401 can also include one or a plurality of substrate processing apparatuses 406 (an etching apparatus and a deposition apparatus). The article manufacturing system 401 further includes an evaluation apparatus 407 that evaluates a film (for example, a cured film of the imprint material in which a pattern is formed) formed on the substrate S by the imprint apparatus IMP (film forming apparatus), as will be described later. The article manufacturing system 401 includes a generation apparatus 408 that generates training data of an evaluation model used to evaluate the film formed on the substrate S in the evaluation apparatus 407, as will be described later. These apparatuses can be connected to a control apparatus 403, which is an external apparatus different from the imprint apparatus IMP, via a network 402 and controlled by the control apparatus 403.

The evaluation apparatus 407 and the generation apparatus 408 can each be formed by an information processing apparatus (computer) including a processor such as a central processing unit (CPU), and a storage unit such as a memory. The information processing apparatus may be formed by, for example, a PLD (a short for Programmable Logic Device) such as an FPGA (a short for Field Programmable Gate Array), an ASIC (a short for Application Specific Integrated Circuit), a general-purpose computer installed with a program, or a combination of all or some of these components. Note that in this embodiment, the evaluation apparatus 407 and the generation apparatus 408 are formed by different information processing apparatuses, but these may be formed by one information processing apparatus.

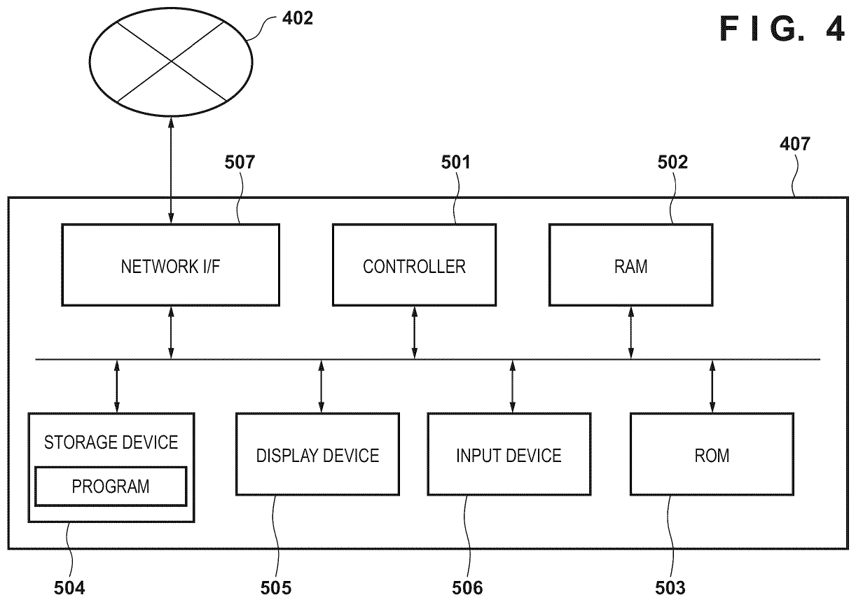

FIG. 4 shows an example of the configuration of the evaluation apparatus 407. The evaluation apparatus 407 can include a controller 501, a RAM 502 that stores temporary data and provides a work area to the controller 501, and a ROM 503 that stores permanent data and programs. The evaluation apparatus 407 can further include a storage device 504, a display device 505, and an input device 506. The storage device 504 stores a program (evaluation program) configured to execute an evaluation method of evaluating a film formed on the substrate S by the imprint apparatus IMP, and a program (learning program) that executes a learning method of an evaluation model for evaluating the film. A network I/F 507 is an interface for connection with the network 402. In this embodiment, the network I/F 507 can function as an obtaining unit that obtains an image including a composition formed on a substrate by a film forming process. Further, the controller 501 can function as an image processing unit that processes the obtained image for evaluation. The controller 501 can also function as a display controller that controls display of the display device 505.

Here, the configuration example of the evaluation apparatus 407 shown in FIG. 4 can also be applied to the generation apparatus 408. That is, the generation apparatus 408 can include the controller 501, the RAM 502, the ROM 503, the storage device 504, the display device 505, the input device 506, and the network I/F 507, like the evaluation apparatus 407. In this case, the storage device 504 stores a program (generation program) configured to execute a generation method for generating training data of an evaluation model.

Note that the functions of the evaluation apparatus 407 and the generation apparatus 408 may be implemented by one of the controller 110 of the imprint apparatus IMP, the control apparatus 403, and the controller of the inspection apparatus 405, or a combination thereof. In this embodiment, a system including the imprint apparatus IMP and the evaluation apparatus 407 may be understood as a film forming system (lithography system). The film forming system may further include the generation apparatus 408.

A lithography method according to this embodiment will be described below. In this embodiment, after performing the imprint process, an image of a region including a shot region (film forming region) where the film of the imprint material IM is formed by the imprint process and its vicinity is obtained by image capturing. Using this image, the film of the imprint material IM (composition portion) formed on the substrate S is evaluated. That is, an abnormality such as protrusion or unfilling that occurs in the film of the imprint material IM is detected. Machine learning is used to detect an abnormality such as protrusion or unfilling. In the machine learning, abnormality detection can be implemented using an object detection algorithm.

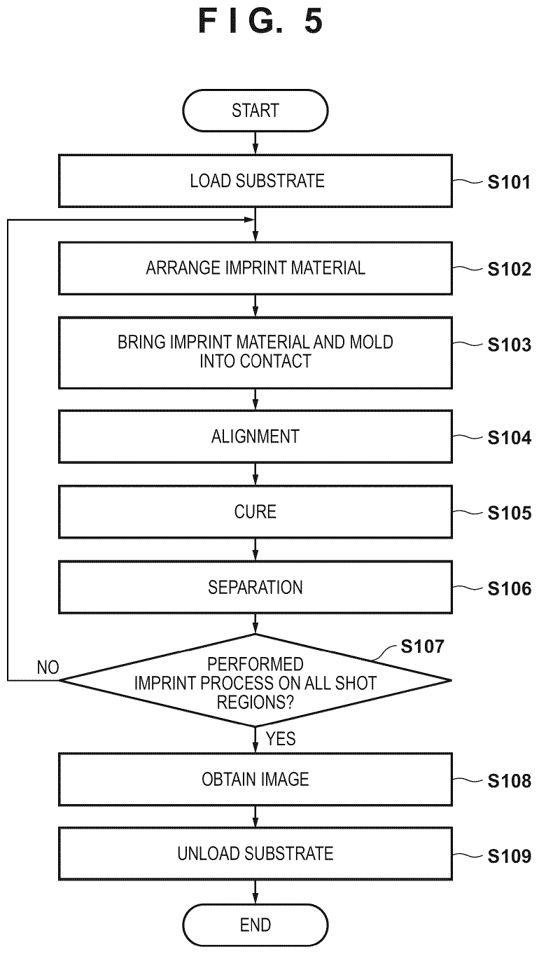

The operation of the imprint apparatus IMP will be described with reference to the flowchart of FIG. 5. The operation shown in FIG. 5 can be executed by the controller 110.

In step S101, the substrate S is conveyed, by a substrate conveyance mechanism (not shown), from a conveyance source (for example, a relay portion between a preprocessing apparatus and the imprint apparatus IMP) onto the substrate holder 102. At this time, the position of the conveyed substrate S on the substrate holder 102 is measured by observing the mark on the substrate S using the wide-angle alignment measurement device 151. The controller 110 positions the substrate S based on the position obtained by the measurement.

Steps S102 to S106 are steps of executing an imprint process for a shot region among the plurality of shot regions on the substrate S, on which the imprint process (pattern formation) is to be performed. The shot region on which the imprint process is to be performed will sometimes be referred to as a target shot region hereinafter.

In step S102, the imprint material IM is arranged (supplied) on the target shot region by the dispenser 108. This processing can be performed by discharging the imprint material IM from the dispenser 108 while driving the substrate S with respect to the dispenser 108 by the substrate driving mechanism 105.

In step S103, the substrate S and the mold M are driven relatively by at least one of the mold driving mechanism 122 and the substrate driving mechanism 105 such that the pattern region MP of the mold M is brought into contact with the imprint material IM on the target shot region. In one example, the mold M is driven by the mold driving mechanism 122 such that the pattern region MP of the mold M is brought into contact with the imprint material IM on the target shot region. In the processing of bringing the pattern region MP of the mold M into contact with the imprint material IM, the pattern region MP of the mold M can be deformed into a convex shape toward the substrate S by the deformation mechanism 123.

In step S104, alignment between the target shot region and the pattern region MP of the mold M can be performed. The alignment can be performed, while measuring the relative position between the alignment mark of the target shot region and the alignment mark of the mold M by the alignment measurement device 106, so as to make the relative position fall within an allowable range of a target relative position. In the alignment, the substrate S and the mold M are driven relatively by at least one of the mold driving mechanism 122 and the substrate driving mechanism 105. The target relative position between the alignment mark of the target shot region and the alignment mark of the mold M can be decided based on a correction value determined from a past result of the overlay inspection apparatus or the like.

In step S105, the curing unit 107 applies the energy for curing the imprint material IM to the imprint material IM between the substrate S and the pattern region MP of the mold M. With this, the imprint material IM is cured, and a cured product (cured film) of the imprint material IM is formed.

In step S106, the substrate S and the mold M are driven relatively by at least one of the mold driving mechanism 122 and the substrate driving mechanism 105 so as to separate the cured product of the imprint material IM from the pattern region MP of the mold M. In one example, the mold M is driven by the mold driving mechanism 122 so as to separate the cured product of the imprint material IM from the pattern region MP of the mold M. Also when separating the cured product of the imprint material IM from the pattern region MP of the mold M, the pattern region MP of the mold M can be deformed into a convex shape toward the substrate S. Further, image capturing by the image capturing unit 112 is performed, and the separation state between the imprint material IM and the mold M is observed based on the captured image.

In step S107, the controller 110 determines whether the imprint process in steps S102 to S106 has been performed for all the shot regions of the substrate S. If the imprint process in steps S102 to S106 has been performed for all the shot regions of the substrate S, the process advances to step S108. If there is any unprocessed shot region, the process returns to step S102. In this case, the imprint process in steps S102 to S106 is performed for the target shot region that is a shot region selected from the unprocessed shot regions.

In step S108, an image of a region (evaluation region) including the shot region (film forming region) after the imprint process is obtained as an evaluation image used to evaluate the film (cured film) formed on the substrate S by the imprint process. For example, the controller 110 uses the wide-angle alignment measurement device 151 to capture an image of the shot region and its vicinity. If the field of the wide-angle alignment measurement device 151 is narrower than the shot region, a plurality of images may be captured to obtain the image of the desired region while changing the position of the substrate S with respect to the field of the wide-angle alignment measurement device 151 by driving the substrate driving mechanism 105. The image obtained in step S108 can be used as input data (evaluation image) of an evaluation model used to evaluate (detect) an abnormality of the cured film on the substrate S, but may be used as training data (learning image) for performing machine learning of the evaluation model. In this embodiment, an example in which an image is captured by the wide-angle alignment measurement device 151 will be described here. However, the present invention is not limited to this and, for example, an image may be captured using the alignment measurement device 106 or the image capturing unit 112.

In the procedure described above, image obtaining (step S108) is performed after the imprint process is performed for all the plurality of shot regions, but the present invention is not limited to this. For example, image obtaining may be performed for each shot region by the same method as in step S108 after the pattern is formed in each shot region (after step S106). Further, for the substrate S unloaded from the imprint apparatus, image obtaining may be performed by the same method as step S108 by an apparatus other than the imprint apparatus.

In step S109, the substrate S is conveyed from the substrate holder 102 to a conveyance destination (for example, a relay portion between the imprint apparatus IMP and a post-processing apparatus) by a substrate conveyance mechanism (not shown). When processing a lot formed by a plurality of substrates, the operation shown in FIG. 5 is performed for each of the plurality of substrates.

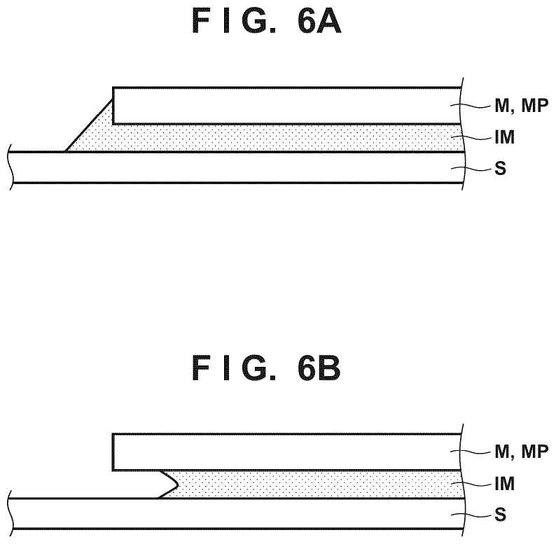

Next, an example of an abnormality that occurs in the imprint process will be described. Each of FIGS. 6A and 6B is a side view showing a state in which the mold M and the imprint material IM on the substrate S are in contact with each other (after step S103 is completed, for example, in steps S104 and S105). Protrusion indicates a state in which the imprint material IM protrudes from the pattern region MP of the mold M, as shown in FIG. 6A. Also, unfilling indicates a state in which a portion where the imprint material IM is not filled between the mold M and the substrate S is generated, as shown in FIG. 6B.

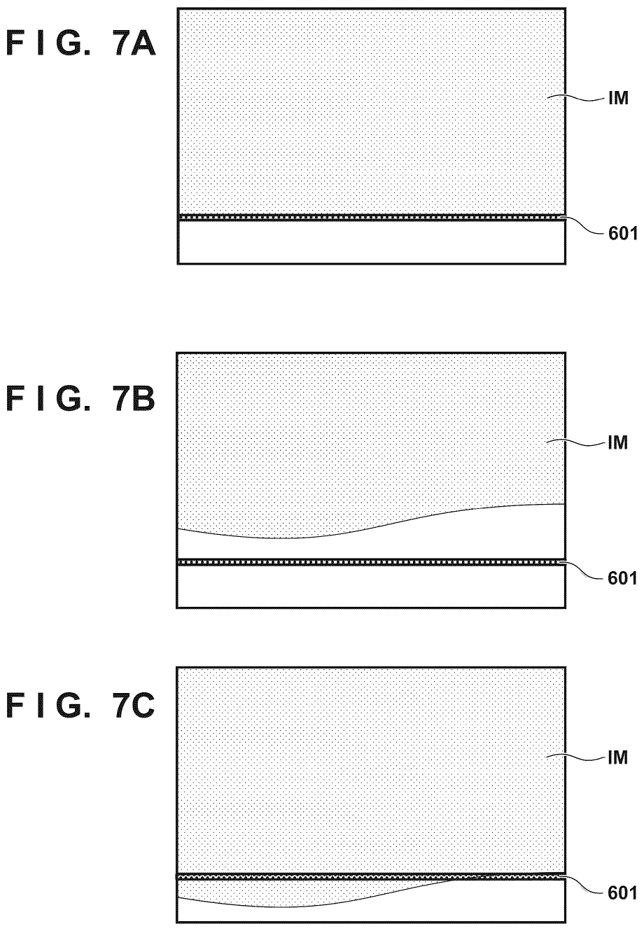

If an abnormality such as protrusion or unfilling occurs, in step S108, images as shown in FIG. 7A to 7C are obtained. FIGS. 7A to 7C are views showing examples of images obtained in step S108 when an abnormality such as protrusion or unfilling occurs. Each of FIGS. 7A to 7C shows an image including a shot region where the cured film (pattern) of the imprint material IM is formed by the imprint process and its vicinity. In a normal state (that is, in a state in which no abnormality occurs), as shown in FIG. 7A, the imprint material IM is filled up to a boundary 601 of the shot region, and the imprint material IM does not protrude on the outside of the boundary 601. On the other hand, in a case of unfilling, as shown in FIG. 7B, a portion where the imprint material IM is not filled up to the boundary 601 of the shot region is captured white (or black). In a case of protrusion, as shown in FIG. 7C, the imprint material IM that protrudes from the boundary 601 of the shot region is captured black (or white).

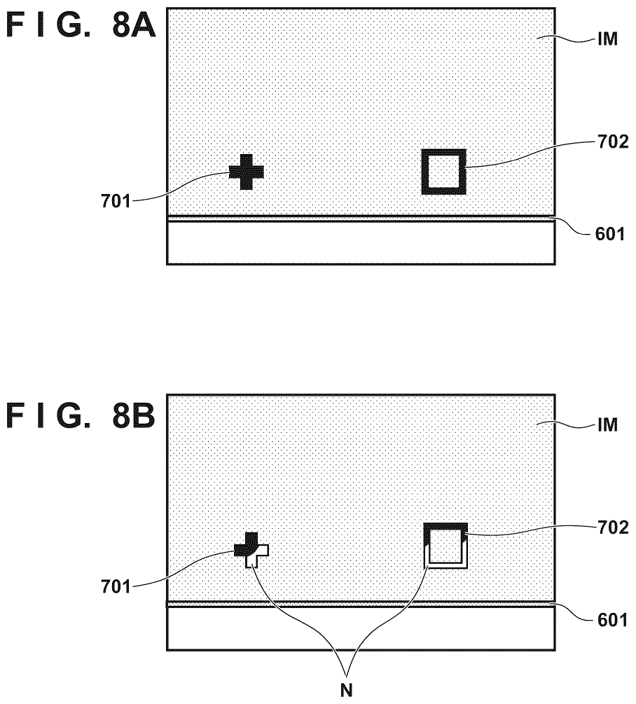

FIGS. 8A and 8B show an example of unfilling that occurs in marks used in alignment or inspection. Each of FIGS. 8A and 8B shows an image obtained by capturing an image of the peripheral portion of a shot region and its vicinity. The region shown in gray in each image is an inspection target shot region filled with the imprint material IM. The shot region includes a first mark 701 and a second mark 702 having different shapes. In FIG. 8A, each of the first mark 701 and the second mark 702 is shown in black. This indicates a normal state in which the imprint material IM is filled inside the mark. On the other hand, in FIG. 8B, a part of each of the first mark 701 and the second mark 702 is shown in white. This indicates a state in which the imprint material IM is not sufficiently filled inside the mark, and an unfilling region N occurs.

If protrusion as described above occurs, in the imprint process of the shot region to which the imprint material IM has protruded, the protruded and cured imprint material IM may come in contact with the mold M and break the pattern of the mold M. If unfilling occurs, no pattern is formed there, and the product is defective as a semiconductor device. Hence, it is necessary to observe the presence/absence of an abnormality such as protrusion or unfilling after the imprint process and adjust imprint conditions to prevent the failure.

As an example of the adjusting method, the amount of the imprint material IM to be supplied onto the substrate is changed in accordance with the position, the size, and the shape of an abnormality (protrusion or unfilling) that has occurred in the film on the substrate. To do this adjustment, the information of the position, the size, and the shape of an abnormality that has occurred in the film on the substrate, that is, the information (to be sometimes referred to as abnormality information hereinafter) of the position, the size, and the shape of the region where the amount of the imprint material IM is short or excessive needs to be obtained. In this embodiment, abnormality information is obtained from the evaluation image obtained in step S108 using a learned model generated by machine learning. The learned model is a model used to evaluate the film formed on the substrate S, and will sometimes be referred to as an evaluation model hereinafter. The evaluation model receives the evaluation image obtained in step S108 as input data and outputs abnormality information that is the evaluation result of the film formed on the substrate S as output data. As the evaluation model, models to be exemplified below can be used. In a method using these models, whether a detection target object exists is calculated for each pixel of the image, and labeling is performed, thereby obtaining the detailed shape of the object.
Model with Convolutional Neural Network structure
Model having the mechanism of Encoder or Decoder such as U-net
Model based on Region-Convolutional Neural Network (R-CNN)

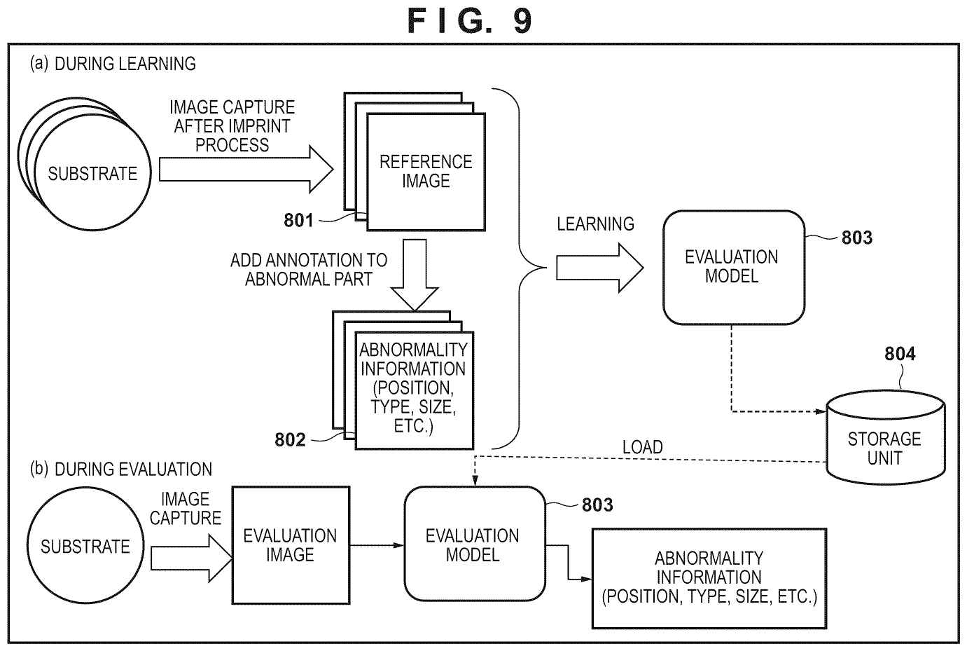

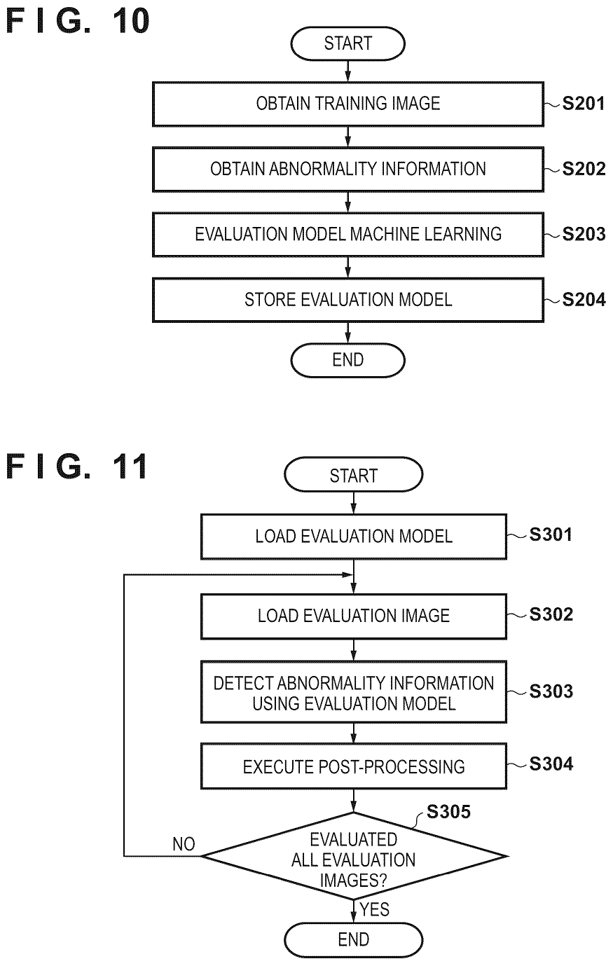

The evaluation model (learned model) used to evaluate the film on the substrate in the evaluation apparatus 407 will be described next with reference to FIGS. 9 to 11. FIG. 9 is a schematic view showing a method of generating the evaluation model by machine learning and a method of evaluating the film on the substrate using the generated evaluation model (that is, a method of obtaining abnormality information generated in the film on the substrate). FIG. 10 is a flowchart showing the method of generating the evaluation model by machine learning. FIG. 11 is a flowchart showing the method (evaluation method) of evaluating the film on the substrate using the evaluation model.

First, the method of generating the evaluation model by machine learning will be described with reference to FIGS. 9 and 10. The method of generating the evaluation model by machine learning may be understood as a learning method of the evaluation model. For example, in the evaluation apparatus 407, a program (learning program) corresponding to the flowchart of FIG. 10 can be stored in the storage device 504, loaded into the RAM 502, and then executed by the controller 501 (image processing unit).

In step S201, the evaluation apparatus 407 obtains a training image 801 (learning image) as training data of the evaluation model. Conventionally, the training image 801 can be obtained by performing the same processing as in step S108 of FIG. 5. More specifically, the training image 801 similar to the evaluation image is obtained based on the conditions of the material and measurement conditions used when obtaining the evaluation image used to evaluate the film on the substrate S. The training image 801 can be, for example, an image obtained by capturing an image of the peripheral portion of a shot region and its vicinity, like the evaluation image. Here, using a plurality of substrates, the training image 801 may be obtained for each of a plurality of shot regions of each substrate. It is preferable that a large number of training images are obtained and a sufficient number of abnormality samples as the detection target are included.

In step S202, the evaluation apparatus 407 obtains abnormality information 802 indicating information about an abnormality (protrusion or unfilling) included in each training image 801 obtained in step S201. Conventionally, an operator visually inspects each training image 801 obtained in step S201, thereby creating, for all abnormalities existing in each training image 801, the abnormality information 802 including information about the categories (types), the sizes, and the positions of abnormalities. The abnormality information 802 thus created and input by the operator can be obtained by the evaluation apparatus 407.

In step S203, the evaluation apparatus 407 performs machine learning of the evaluation model using the training images 801 obtained in step S201 as training data. For example, the evaluation apparatus 407 performs optimization using the training images 801 as input data to a neural network created in advance and the abnormality information 802 as output data (supervisory data). This can generate an evaluation model 803 as a learned model (neural network). Next, in step S204, the evaluation apparatus 407 stores the evaluation model 803 generated in step S203 in a storage unit 804. The storage unit 804 may be understood as the storage device 504 of the evaluation apparatus 407.

A method of evaluating the film on the substrate using the evaluation model (that is, a method of detecting an abnormality that has occurred in the film on the substrate) will be described next with reference to FIGS. 9 and 11. A program (evaluation program) corresponding to the flowchart of FIG. 11 can be stored in, for example, the storage device 504 of the evaluation apparatus 407, loaded into the RAM 502, and then executed by the controller 501 (image processing unit).

In step S301, the evaluation apparatus 407 loads an evaluation model that outputs the evaluation result of the film based on the image of the film formed on the substrate by the imprint apparatus IMP. The evaluation model is a model that, upon receiving the evaluation image of the film formed on the substrate by the imprint apparatus IMP, outputs abnormality information generated in the evaluation image as an evaluation result. The evaluation model is generated in accordance with the above-described flowchart of FIG. 10 based on an image obtained under the conditions similar to the conditions of the imprint material of the inspection target and the measurement conditions of the evaluation image obtained in step S108, and stored in the storage unit 804.

In step S302, the evaluation apparatus 407 loads the evaluation image obtained in step S108. Next, in step S303, based on the evaluation model loaded in step S301 and the evaluation image loaded in step S302, the evaluation apparatus 407 detects abnormality information (the feature of an abnormality) generated in the evaluation image as evaluation of a portion corresponding to the evaluation image of the film on the substrate. More specifically, the evaluation apparatus 407 inputs the evaluation image to the evaluation model, thereby obtaining “abnormality information (the feature of an abnormality) generated in the evaluation image” output from the evaluation model as an evaluation result. The abnormality information (the feature of an abnormality) is obtained for each abnormality existing in the evaluation image. The abnormality information (the feature of an abnormality) can include the type (protrusion/unfilling) of the abnormality, the coordinates of the vertices of a rectangle that surrounds the abnormality region, and the certainty factor of the detected abnormality, in addition to the category (type), the position, the size, and the shape of the abnormality. Here, the certainty factor of the detected abnormality is a value indicating the reliability of the evaluation result (the detection result of the abnormality information), and is automatically calculated by the evaluation model for each detected abnormality. Examples of the type of an abnormality are protrusion and unfilling, as described above. Other types of abnormalities can also be detected by causing the evaluation model to learn those.

In step S304, the evaluation apparatus 407 performs post-processing for the abnormality information obtained by the evaluation model in step S303. For example, the post-processing can include, for the various kinds of abnormalities, comparing the certainty factor of each abnormality with a specific threshold and classifying the abnormalities. As an example, when the certainty factor is expressed by a value from 0 to 1, an abnormality whose certainty factor is 0.5 or less can be classified into abnormalities other than detection targets. The classification conditions such as the threshold used when classifying abnormalities based on the certainty factors can be changed by various kinds of data such as the imprint material as the inspection target, recipe information, light control conditions in image capturing, and the mode in image capturing.

In step S305, the evaluation apparatus 407 determines whether the evaluation result (inspection result) is obtained for all the plurality of evaluation images obtained by the imprint apparatus IMP. If the evaluation result is obtained for all the evaluation images, the processing is ended. On the other hand, if there is an evaluation image whose evaluation result is not obtained yet, the process returns to S302, and steps S302 to S304 are executed for the evaluation image. In this way, steps S302 to S304 are repetitively executed to obtain the evaluation result (inspection result) for each of the plurality of evaluation images obtained by the imprint apparatus IMP.

Note that in the above example, the evaluation apparatus 407 has been described as an information processing apparatus that executes both learning and evaluation (inspection). However, an information processing apparatus that performs learning and an information processing apparatus that performs evaluation (inspection) may be formed as separate apparatuses. In this case, a first information processing apparatus creates an evaluation model, and the evaluation model is transferred to a second information processing apparatus that performs evaluation. Using the evaluation model transferred from the first information processing apparatus, the second information processing apparatus evaluates (inspects) the film on the substrate based on the input evaluation image.

To more accurately generate the evaluation model as described above by machine learning, an enormous number (sufficient number) of training images to which the features of abnormalities are added need to be prepared (collected) in advance as training data. However, it is cumbersome to perform the imprint process to prepare an enormous number of images serving as training data while changing conditions to change the position and size of an abnormality (protrusion or unfilling) included in a training image, and it takes a pretty long time. In addition, if the operator visually inspects each of the enormous number of prepared training images to obtain abnormality information of each training image as supervisory data, the man-hours of the operator may increase. In particular, since the occurrence frequency of an abnormality is hard to control, it may be necessary to execute the imprint process more times to obtain the enormous number of training images usable as the training data of the evaluation model.

In this embodiment, a design image indicating the geometric feature of at least a part of the substrate S is processed, thereby generating a training image serving as training data of the evaluation model. More specifically, the design image is processed, thereby generating a training image to which an abnormality such as protrusion or unfilling, which may occur in the film on the substrate, is artificially added. This makes it possible to easily generate training data (training image) of the evaluation model and reduce execution of the imprint process for preparing training images and the man-hours of the operator. Note that training image generation in this embodiment can be executed by the generation apparatus 408 (controller 501).

First, the basic idea concerning generation of an abnormality (protrusion or unfilling) added to a training image will be described. In this embodiment, a design image indicating the geometric feature of at least a part of the substrate is processed, thereby artificially generating an abnormality such as protrusion or unfilling of the imprint material IM. The design image may be an image including the boundary of a shot region as the geometric feature of at least a part of the substrate S, or may be an image including a mark to be used in alignment or inspection. As an example, a design image including the boundary of a shot region can be an image without an abnormality (protrusion or unfilling), as shown in FIG. 7A. Here, the design image can be obtained from design information represented by the format of the image concerning at least a part of the substrate S, but may be obtained from design information representing at least a part of the substrate by vertices, a line segment, or a polygon. Alternatively, the design image may be obtained by capturing an image or performing measurement using an apparatus for measuring a surface shape for the substrate for which the imprint process is normally performed under the same conditions as the inspection target.

As described above with reference to FIG. 7B, in a case of unfilling, a portion where the imprint material IM is not filled up to the boundary 601 of the shot region is captured white (or black). Hence, when the design image is processed (that is, image processing is performed) such that the region inside the boundary 601 becomes white (black), unfilling of the imprint material IM can artificially be created. On the other hand, as described above with reference to FIG. 7C, in a case of protrusion, the imprint material IM that protrudes from the boundary 601 of the shot region is captured black (or white). Hence, when the design image is processed (that is, image processing is performed) such that the region outside the boundary 601 becomes black (white), protrusion of the imprint material IM can artificially be created.

The same applies to the marks 701 and 702 used in alignment or inspection as for boundary 601 of the shot region. As described above with reference to FIG. 8B, in a case of unfilling, a portion where the imprint material IM is not filled in the marks 701 and 702 is captured white (or black). Hence, when the design image is processed (that is, image processing is performed) such that the part of the marks 701 and 702 becomes white (black), unfilling in the marks 701 and 702 can artificially be created. Here, if bubbles of a gas are accumulated inside the imprint material IM during filing of the imprint material IM, unfilling of the imprint material IM may occur. In this case, the bubbles tend to form a circular shape in a place without any pattern, and in a place where a pattern exists, form a shape conforming to the pattern. Hence, when the design image is processed such that the shape of the region of unfilling is formed in accordance with the tendency, unfilling closer to reality can artificially be created.

Also, in this embodiment, the category (type), the size, and the position of each abnormality artificially added to a training image are known information for the generation apparatus 408 (information processing apparatus) that has generated the training image. For this reason, along with creation of the training image, the generation apparatus 408 can automatically create abnormality information indicating the features (the category, the size, the position, and the like) of the abnormality included in the training image. That is, the generation apparatus 408 can easily generate abnormality information for the training image as supervisory data without visual inspection by the operator.

As described above, in this embodiment, the training image serving as the training data of the evaluation model can easily be generated by processing the design image. The abnormality information as supervisory data of the evaluation model can also be generated easily. That is, in this embodiment, it is possible to easily generate an enormous amount of training data and supervisory data of the evaluation model. Machine learning of the evaluation model can accurately be performed using the enormous amount of training data and supervisory data. As a result, the learned evaluation model can accurately perform evaluation (that is, abnormality detection) of the film of the imprint material IM formed on the substrate by the imprint apparatus IMP based on the evaluation image obtained by actual image capturing in step S108.

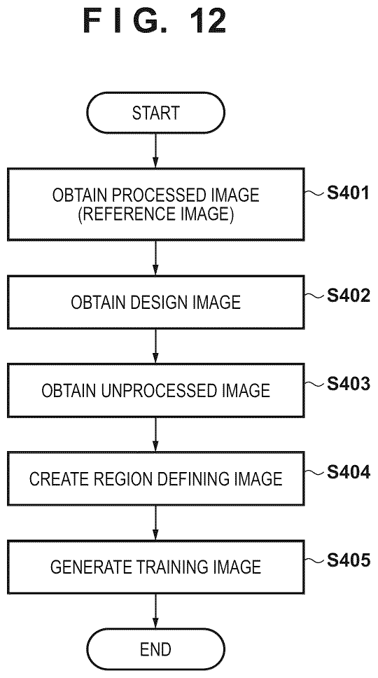

A generation method of generating the training image to which an abnormality is artificially added as the training data of the evaluation model will be described next. FIG. 12 is a flowchart showing the training image generation method. For example, in the generation apparatus 408, a program (generation program) corresponding to the flowchart of FIG. 12 can be stored in the storage device 504, loaded into the RAM 502, and then executed by the controller 501 (image processing unit).

In step S401, the generation apparatus 408 obtains a reference image indicating at least a part of the substrate S. The reference image is an image obtained by actual image capturing in the imprint apparatus IMP, and is preferably an image without an abnormality such as protrusion or unfilling. For example, the reference image can be an image (to be sometimes referred to as a processed image hereinafter) obtained by capturing at least a part of the substrate S on which the film of the imprint material IM is formed by the imprint process. Note that the reference image may be the evaluation image obtained in advance in step S108 described above.

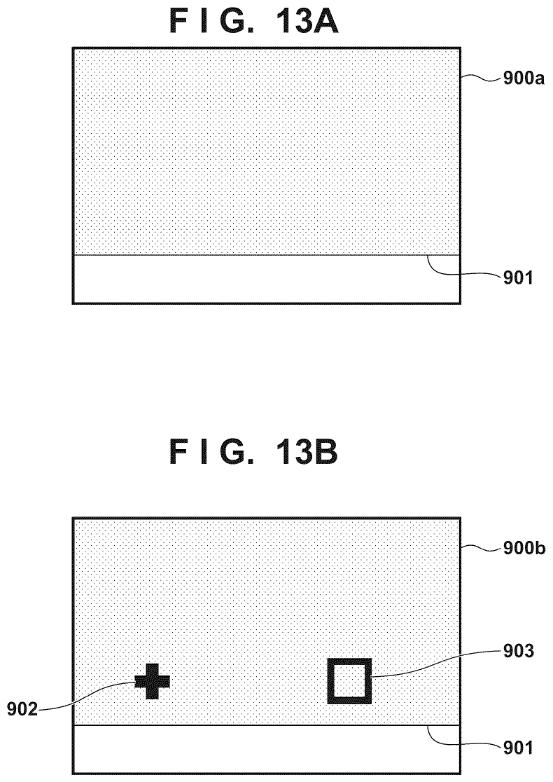

In step S402, the generation apparatus 408 obtains a design image for the same region of the substrate S as the reference image obtained in step S401 (that is, a least the part of the substrate obtained as the reference image). As described above, the design image is an image indicating the geometric feature of the at least a part of the substrate S. The design image may be created from design information represented by the format of the image concerning the at least a part of the substrate S, and may be created from design information representing the at least a part of the substrate by vertices, a line segment, or a polygon. FIGS. 13A and 13B are views showing an example of the design image. A design image 900a shown in FIG. 13A includes a boundary 901 of a shot region (that is the boundary of a region to be filled with the imprint material IM) as the geometric feature of the at least a part of the substrate S. A design image 900b shown in FIG. 13B includes the boundary 901 of the shot region and marks 902 and 903 as the geometric feature of the at least a part of the substrate S. Note that the design image may include not the boundary 901 of the shot region but only the marks 902 and 903.

In step S403, the generation apparatus 408 obtains an image (to be sometimes referred to as an unprocessed image hereinafter) obtained by capturing an image of the substrate S before the film of the imprint material IM is formed by the imprint process. The unprocessed image is preferably obtained under the same image capturing conditions as in obtaining the processed image (reference image). Also, the unprocessed image is used as an image indicating an abnormality (protrusion or unfilling) artificially added to the processed image (reference image). That is, the unprocessed image is used as an image indicating a pseudo abnormality added to an abnormality adding region defined by a region defining image to be described later.

In step S404, based on the design image obtained in step S402, the generation apparatus 408 creates a region defining image used to define an abnormality adding region in the processed image (reference image) obtained in step S401. The abnormality adding region is a region to which an abnormality (protrusion or unfilling) should artificially be added in the processed image (reference image). The region defining image is an image indicating the position, the size, the shape, and the like of the abnormality adding region in the processed image (reference image). For example, the generation apparatus 408 can create the region defining image by processing the design image obtained in step S402 (that is, performing image processing). A detailed example of creating the region defining image in step S403 will be described later.

In step S405, based on the region defining image created in step S404, the generation apparatus 408 artificially adds an abnormality to the abnormality adding region of the processed image (reference image) obtained in step S401, thereby generating a training image. That is, the generation apparatus 408 generates, as the training image, the image obtained by artificially adding an abnormality to the abnormality adding region of the processed image (reference image). As the image indicating the abnormality artificially added to the abnormality adding region of the processed image (reference image), the unprocessed image obtained in step S403 is used. A detailed example of generating the training image in step S404 will be described later.

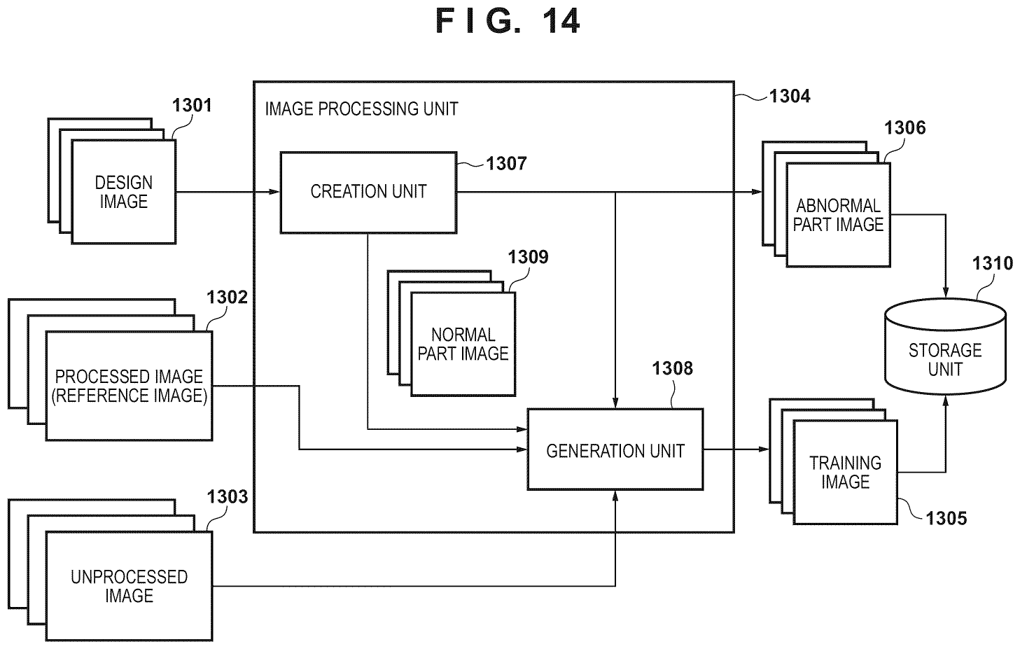

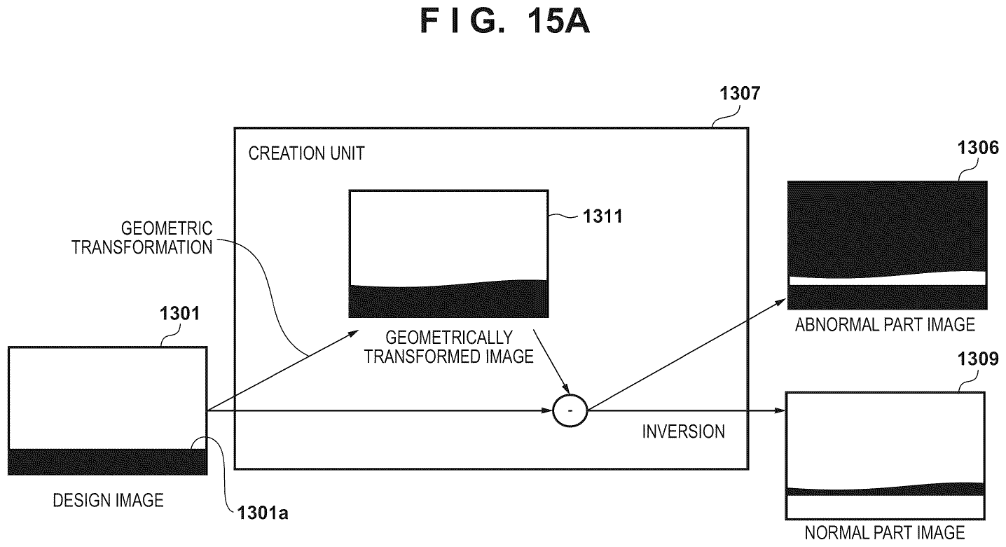

FIG. 14 is a schematic view for explaining processing performed by the generation apparatus 408. As described above, a design image 1301 is obtained in step S402, a processed image 1302 as a reference image is obtained in step S401, and an unprocessed image 1303 is obtained in step S403. These images (the design image 1301, the processed image 1302, and the unprocessed image 1303) are input to an image processing unit 1304 (controller 501) of the generation apparatus 408. The image processing unit 1304 can include a creation unit 1307 and a generation unit 1308.

The creation unit 1307 creates an abnormal part image 1306 and a normal part image 1309 based on the design image 1301. The abnormal part image 1306 is an image used to open the abnormality adding region of the processed image 1302 (reference image) and mask a region other than the abnormality adding region. That is, the abnormal part image 1306 is an image that masks the region other than the abnormality adding region such that an abnormality is added only to the abnormality adding region, and the abnormality is not added to the region other than the abnormality adding region. The abnormal part image 1306 may be understood as a region defining image used to define the abnormality adding region in the processed image 1302 (reference image). The normal part image 1309 is an image used to open the region other than the abnormality adding region of the processed image 1302 (reference image) and mask the abnormality adding region. The normal part image 1309 may be understood as an image obtained by inverting the mask region in the abnormal part image 1306. The abnormal part image 1306 and the normal part image 1309 created by the creation unit 1307 are input to the generation unit 1308.

Based on the design image 1301, the processed image 1302 (reference image), the unprocessed image 1303, the abnormal part image 1306, and the normal part image 1309, the generation unit 1308 generates a training image 1305 to which an abnormality is artificially added. The training image 1305 may be understood as a pseudo defect image having a pseudo defect. The abnormal part image 1306 created by the creation unit 1307 and the training image 1305 generated by the generation unit 1308 are stored in a storage unit 1310 (for example, the storage device 504).

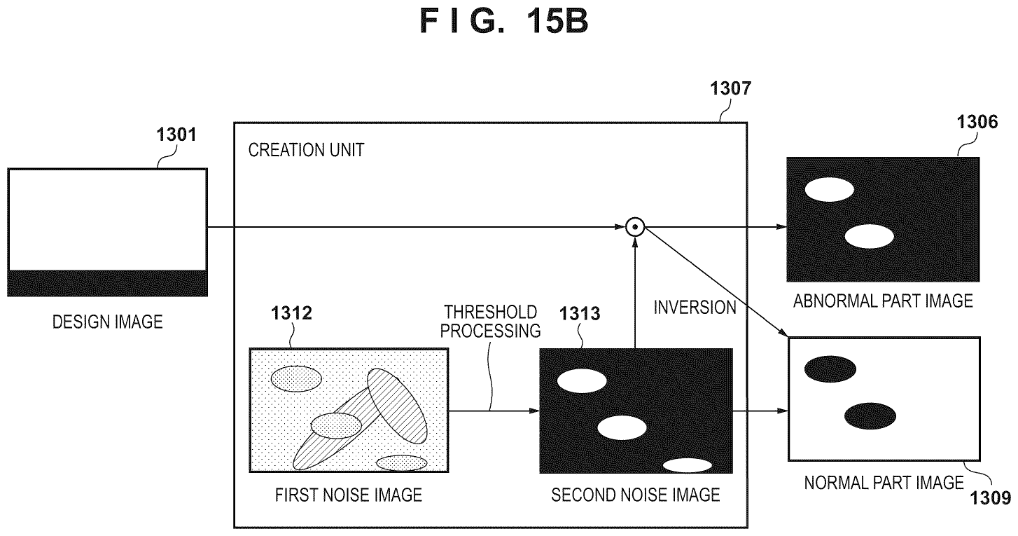

Contents of processing performed by the creation unit 1307 will be described next with reference to FIGS. 15A and 15B. FIGS. 15A and 15B are schematic views for explaining processing performed by the creation unit 1307. Note that in each of the abnormal part image 1306 and the normal part image 1309 shown in FIGS. 15A and 15B, a white portion indicates an opened region, and a black portion indicates a masked region.

The creation unit 1307 creates (outputs) the abnormal part image 1306 used to define the abnormality adding region in the processed image 1302 (reference image) and the normal part image 1309 that is an inverted image of the abnormal part image 1306. Each of the abnormal part image 1306 and the normal part image 1309 is a two-dimensional image in which each pixel has a value “0” or “1”. Upon receiving the design image 1301, the creation unit 1307 creates, based on the design image 1301, the abnormal part image 1306 by imparting restrictions to the region to add an abnormality (protrusion or unfilling). Also, the creation unit 1307 creates the normal part image 1309 by inverting the mask region in the abnormal part image 1306.

For example, to add a pseudo defect simulating unfilling, as shown in FIG. 15A, the creation unit 1307 performs geometric transformation of the geometric feature in the design image 1301, thereby generating a geometrically transformed image 1311 (first image). FIG. 15A exemplarily shows a boundary 1301a of a shot region as the geometric feature in the design image 1301. The creation unit 1307 calculates the difference between the design image 1301 and the geometrically transformed image 1311, and creates the abnormal part image 1306 in which the region where the difference is generated is opened as the abnormality adding region, and the region other than the abnormality adding region is masked. Also, the creation unit 1307 creates the normal part image 1309 by inverting the mask region in the abnormal part image 1306.

The creation unit 1307 may create the abnormal part image 1306 and the normal part image 1309 by adding a noise component to the design image 1301, as shown in FIG. 15B. In this case, the creation unit 1307, for example, generates a first noise image 1312 using a texture creation method such as Perlin noise, and generates a second noise image 1313 by performing threshold processing (image binarization) for the first noise image 1312. The first noise image 1312 may be understood as an image having a random noise pattern. The second noise image 1313 is a noise image obtained by performing threshold processing for each pixel of the first noise image 1312, and may be understood as an image (second image) having a noise component to be added to the design image 1301. The creation unit 1307 creates the abnormal part image 1306 by calculating the Hadamard product between the design image 1301 and the second noise image. In addition, the creation unit 1307 creates the normal part image 1309 by inverting the mask region in the abnormal part image 1306.

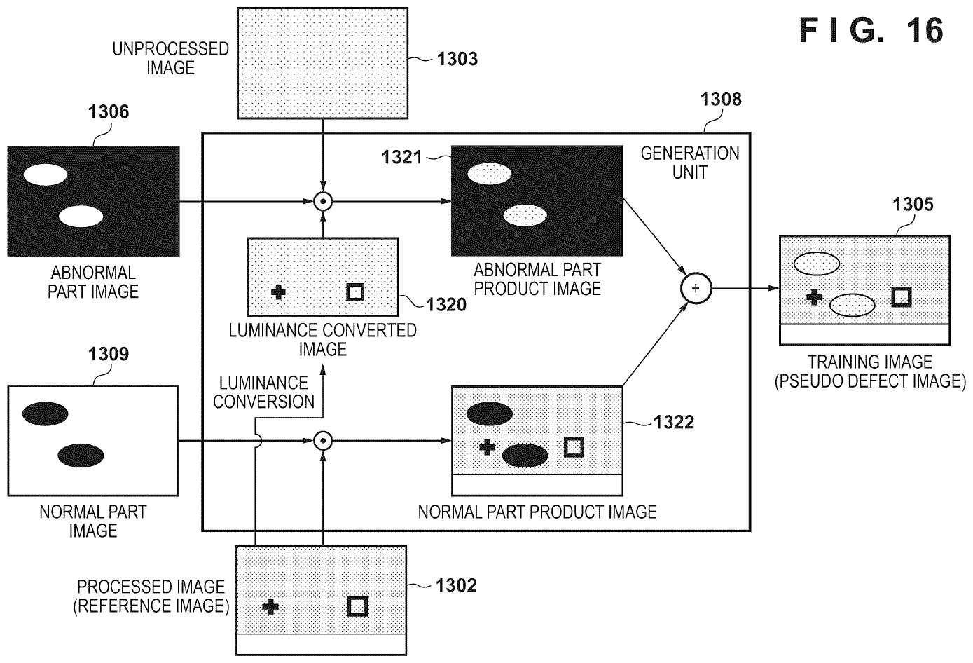

Contents of processing performed by the generation unit 1308 will be described next with reference to FIG. 16. FIG. 16 is a schematic view for explaining processing performed by the generation unit 1308. Note that FIG. 16 shows an example in which the training image 1305 (pseudo defect image) is generated using the abnormal part image 1306 and the normal part image 1309 created by adding a noise component to the design image 1301, as shown in FIG. 15B. However, even in a case where the abnormal part image 1306 and the normal part image 1309 created by performing geometric transformation of the design image 1301 are used, as shown in FIG. 15A, the training image 1305 can be generated by the same method.

The generation unit 1308 calculates the Hadamard product between the abnormal part image 1306 and the unprocessed image 1303, thereby generating an abnormal part product image 1321 including the unprocessed image 1303 reflected on (inserted into) the opening region (white portion) of the abnormal part image 1306. Here, in place of the unprocessed image 1303, the generation unit 1308 may use a luminance converted image 1320 obtained by converting the luminance of the processed image 1302 (reference image). The luminance converted image 1320 is generated by, for example, converting the luminance of the processed image 1302 such that it substantially equals the luminance of the image of the substrate S before the imprint process is performed, and is used as an image indicating an abnormality artificially added to the processed image 1302. In this case, the generation unit 1308 generates the abnormal part product image 1321 by calculating the Hadamard product between the abnormal part image 1306 and the luminance converted image 1320.

Also, the generation unit 1308 calculates the Hadamard product between the normal part image 1309 and the processed image 1302 (reference image), thereby generating a normal part product image 1322 including the processed image 1302 reflected on (inserted into) the opening region (white portion) of the normal part image 1309. The generation unit 1308 then adds the abnormal part product image 1321 and the normal part product image 1322. The generation unit 1308 can thus generate the training image 1305 (pseudo defect image) formed by artificially adding an abnormality to the abnormality adding region of the processed image 1302 (reference image).

In this embodiment, unfilling has been exemplified. However, the training image 1305 can be generated even for protrusion, an abnormality of a mark, or an abnormality of a pattern other than the mark formed on the shot region or a mark or a pattern in the shot region, as in the case of unfilling. Also, in this embodiment, an example in which the training image is generated using the unprocessed image 1303 or the luminance converted image 1320 has been described. However, the present invention is not limited to this. For example, without using the unprocessed image 1303 or the luminance converted image 1320, the training image 1305 can be generated by directly adding the abnormal part image 1306 to the processed image 1302 or multiplying these. In particular, protrusion often appears extremely black in a normal region, and the training image 1305 to which an abnormality is artificially added at high accuracy can be generated without using the unprocessed image 1303. In this case, step S403 shown in FIG. 12 can be omitted.

In this embodiment, post-processing such as smoothing processing or contrast adjustment may be executed for the abnormal part image 1306, the normal part image 1309, and/or the training image 1305 generated in the above-described way. By executing post-processing, the training image 1305 to which an abnormality is artificially added at higher accuracy can be generated. Also, in this embodiment, an example in which learning of the evaluation model is performed using the training image 1305 generated in steps S401 to S405 in FIG. 12 as training data has been described. However, the present invention is not limited to this, and learning of the evaluation model may be performed using not only the training image 1305 but also an image visually inspected by the operator as described concerning step S202 of FIG. 10 or abnormality information as training data.

As described above, in this embodiment, the design image 1301 indicating the geometric feature of at least a part of the substrate S is processed, thereby generating, as the training data of the evaluation model, the training image 1305 to which an abnormality that may occur in the film on the substrate is artificially added. According to this embodiment, it is possible to easily generate the training data (training image) of the evaluation model and reduce execution of the imprint process for preparing training images and the man-hours of the operator.

### Embodiment of Article Manufacturing Method

An article manufacturing method according to the embodiment of the present invention is suitable to, for example, manufacture an article such as a microdevice such as a semiconductor device or an element having a microstructure. The article manufacturing method according to this embodiment includes a forming step of forming a film of a composition on a substrate by a film forming apparatus (for example, an imprint apparatus) in a film forming system, a processing step of processing the substrate that has undergone the forming step, and a manufacturing step of manufacturing an article from the substrate that has undergone the processing step. The manufacturing method also includes other known steps (oxidation, deposition, vapor deposition, doping, planarization, etching, resist peeling, dicing, bonding, and packaging). The article manufacturing method according to this embodiment is advantageous in at least one of the performance, quality, productivity, and production cost of an article as compared to a conventional method.

If an imprint apparatus is used as the film forming apparatus, the pattern of the cured product formed using the imprint apparatus is used permanently for at least some of various kinds of articles or temporarily when manufacturing various kinds of articles. The articles are an electric circuit element, an optical element, a MEMS, a recording element, a sensor, a mold, and the like. Examples of the electric circuit element are volatile and nonvolatile semiconductor memories such as a DRAM, an SRAM, a flash memory, and an MRAM and semiconductor elements such as an LSI, a CCD, an image sensor, and an FPGA. Examples of the mold are molds for imprint.

The pattern of the cured product is directly used as the constituent member of at least some of the above-described articles or used temporarily as a resist mask. After etching or ion implantation is performed in the substrate processing step, the resist mask is removed.

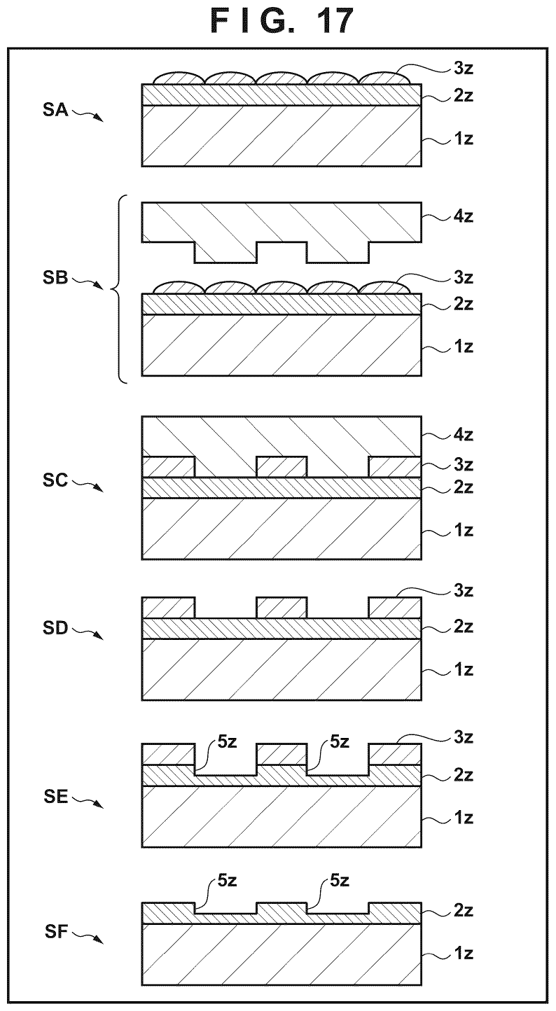

A detailed article manufacturing method will be described next. Here, an example of the article manufacturing method using an imprint apparatus will be described with reference to FIG. 17. In a step SA shown in FIG. 17, a substrate 1z such as a silicon substrate with a processed material 2z such as an insulator formed on the surface is prepared. Next, an imprint material 3z is applied to the surface of the processed material 2z by an inkjet method or the like. A state in which the imprint material 3z is applied as a plurality of droplets onto the substrate is shown here.

In a step SB shown in FIG. 17, a side of a mold 4z for imprint with a concave-convex pattern is directed to face the imprint material 3z on the substrate. In a step SC shown in FIG. 17, the substrate 1z to which the imprint material 3z has been applied is brought into contact with the mold 4z, and a pressure is applied. The gap between the mold 4z and the processed material 2z is filled with the imprint material 3z. In this state, when the imprint material 3z is irradiated with light as curing energy via the mold 4z, the imprint material 3z is cured.

In a step SD shown in FIG. 17, after the imprint material 3z is cured, the mold 4z is separated from the substrate 1z, and the pattern of the cured product of the imprint material 3z is formed on the substrate 1z. In the pattern of the cured product, the concave portion of the mold corresponds to the convex portion of the cured product, and the convex portion of the mold corresponds to the concave portion of the cured product. That is, the concave-convex pattern of the mold 4z is transferred to the imprint material 3z.

In a step SE shown in FIG. 17, when etching is performed using the pattern of the cured product as an etching resistant mask, a portion of the surface of the processed material 2z where the cured product does not exist or remains thin is removed to form a groove 5z. In a step SF shown in FIG. 17, when the pattern of the cured product is removed, an article with the grooves 5z formed in the surface of the processed material 2z can be obtained. Here, the pattern of the cured product is removed. However, instead of removing the pattern of the cured product after the process, it may be used as, for example, an interlayer dielectric film included in a semiconductor element or the like, that is, a constituent member of an article.

### Other Embodiments

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-168867 filed on Sep. 28, 2023, which is hereby incorporated by reference herein in its entirety.

What is claimed is:

1. A generation method of generating, by an information processing apparatus, training data of a model used to evaluate a film of a composition formed on a substrate using a mold, comprising:
generating a training image as the training data by processing a design image indicating a geometric feature of at least a part of the substrate.

2. The method according to claim 1, wherein the design image is processed, thereby generating the training image to which an abnormality that may occur in the film is artificially added.

3. The method according to claim 2, wherein a region defining image for defining an abnormality adding region in a reference image indicating the at least a part is created based on the design image, and the training image is generated by artificially adding the abnormality to the abnormality adding region of the reference image based on the region defining image.

4. The method according to claim 3, wherein geometric transformation of the geometric feature in the design image is performed, and the region defining image is created based on a first image obtained by the geometric transformation.

5. The method according to claim 4, wherein an image in which a region where a difference is generated between the design image and the first image is set to the abnormality adding region is created as the region defining image.

6. The method according to claim 3, wherein the region defining image is created based on the design image and a second image including a noise component.

7. The method according to claim 3, wherein based on the region defining image, a part of an image obtained by converting a luminance of the reference image is artificially added as the abnormality to the abnormality adding region of the reference image, thereby generating the training image.

8. The method according to claim 3, wherein based on the region defining image, a part of an image of the substrate before the film is formed is artificially added as the abnormality to the abnormality adding region of the reference image, thereby generating the training image.

9. The method according to claim 2, wherein the abnormality includes at least one of protrusion of the composition from a region on the substrate where the film should be formed, and unfilling of the composition in the region.

10. The method according to claim 1, wherein the design image includes, as the geometric feature, information of a boundary of a region where a pattern should be formed among the substrate.

11. The method according to claim 1, wherein the design image includes, as the geometric feature, information of a mark that should be formed on the substrate.

12. The method according to claim 1, wherein the design image is obtained from design information represented by a format of an image concerning the at least a part.

13. The method according to claim 1, wherein the design image is obtained from design information representing the at least a part by vertices, a line segment, or a polygon.

14. A non-transitory computer-readable storage medium storing a program for causing a computer to execute a generation method according to claim 1.

15. A method of learning a model that receives an image of a film of a composition formed on a substrate using a mold as an input, thereby outputting an evaluation result of the film, comprising:
performing learning of the model using, as training data, a training image generated by a generation method defined in claim 1.

16. A non-transitory computer-readable storage medium storing a program for causing a computer to execute a learning method according to claim 15.

17. A generation apparatus for generating training data of a model used to evaluate a film of a composition formed on a substrate using a mold, wherein
a training image as the training data is generated by processing a design image indicating a geometric feature of at least a part of the substrate.

18. An evaluation apparatus for evaluating a film of a composition formed on a substrate using a mold, comprising:
a model configured to receive an image of the film, thereby outputting an evaluation result of the film,
wherein learning of the model is performed using, as training data, a training image generated by a generation apparatus defined in claim 17.

19. A film forming system comprising:
a film forming apparatus configured to form a film of a composition on a substrate using a mold; and
an evaluation apparatus defined in claim 18, which is configured to evaluate the film based on an image of the film formed on the substrate by the film forming apparatus.

20. An article manufacturing method comprising:
forming a film of a composition on a substrate by a film forming apparatus in a film forming system defined in claim 19;
processing the substrate that has undergone the forming; and
manufacturing an article from the substrate that has undergone the processing.
